(19) United States
(12) Patent Application Publication
(10) Pub. No.: US 2025/0293099 A1
(43) Pub. Date: Sep. 18, 2025

(54) SAME-SIDE COMBINED ELECTRICAL/OPTICAL TESTING AT MULTIPLE IC DEVICE FABRICATION STAGES

(71) Applicant: Taiwan Semiconductor Manufacturing Company, Ltd., Hsinchu (TW)

(72) Inventor: Xin-Hua Huang, Xihu Township (TW)

(21) Appl. No.: 18/602,104

(22) Filed: Mar. 12, 2024

(51) Int. Cl. H01L 21/66; G01R 31/28

(52) U.S. Cl. CPC H01L 22/34; G01R 31/2851

(57) ABSTRACT

Some embodiments relate to an integrated circuit (IC) device that includes a substrate including a first surface and a second surface, a first dielectric layer disposed over the second surface of the substrate, a photodetector and an optical edge coupler disposed in the first dielectric layer, at least one dielectric layer disposed over the first dielectric layer, a conductive structure disposed in the at least one dielectric layer, a conductive pad disposed at a surface of the IC device, and a trench extending from the surface of the IC device toward the substrate. The conductive pad is electrically coupled to the photodetector by way of the conductive structure. The optical edge coupler is optically coupled to the photodetector and configured to receive light from a sidewall of the trench.

### BACKGROUND

A result of continued development in integrated circuit (IC) technology is the increased integration of electrical and optical functionality in a single IC device. To support such integration, yield testing of both electrical functions (e.g., using circuit probe (CP) testing) and optical functions of the device (e.g., using a laser for optical testing input) is performed prior to customer delivery to reduce or eliminate the provision of non-functional or poor-performing IC devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate schematic perspective and plan views, respectively, of some embodiments of fabrication of an integrated circuit (IC) device that facilitates same-side electrical and optical testing at multiple stages of fabrication, according to the present disclosure.

FIGS. 1C and 1D illustrate schematic side views of some embodiments of a photonic IC (P-IC) structure and subsequent combined structure, respectively, that facilitate same-side electrical and optical testing at different stages of fabrication, according to the present disclosure.

FIGS. 2A and 2B illustrate structural side and plan views, respectively, of some embodiments of a P-IC structure that facilitates same-side electrical and optical testing at a corresponding stage of fabrication, according to the present disclosure.

FIGS. 3A and 3B illustrate structural side and plan views, respectively, of some embodiments of a combined P-IC/Electrical IC (E-IC) structure that facilitates same-side electrical and optical testing at a corresponding stage of fabrication, according to the present disclosure.

FIGS. 4A and 4B illustrate structural plan and side views, respectively, of some embodiments of an optical edge coupler for an IC device that facilitates same-side electrical and optical testing at multiple stages of fabrication, according to the present disclosure.

FIGS. 5A through 5K illustrate cross-sectional views of some embodiments of a semiconductor structure including an optical edge coupler for an IC device that facilitates same-side electrical and optical testing at multiple stages of fabrication, according to the present disclosure.

FIGS. 6A and 6B illustrate a methodology of forming the semiconductor structure of FIGS. 5A through 5K, in accordance with some embodiments.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As further integration of optical and associated electrical functions in a single IC device continues, the simultaneous testing of both types of functionality in the device is considered important from both a photonics wafer acceptance test (WAT) or optical WAT (oWAT) point of view and a chip probe (CP) testing perspective. However, this simultaneous testing may be challenging, as accessible electrical input/output (I/O) points may be positioned on an opposite side of the device from the optical I/O locations, and some testing equipment and processes may not be compatible with accessing both sides of the IC device simultaneously. Providing testing optical I/O paths that are on the opposing side of the device from the optical I/O paths used during normal operation may be possible. However, these testing paths may suffer from significant optical signal loss due to undesirable diffraction and scattering effects, thus rendering the associated optical testing less effective.

In addition, providing such testing at a single stage in device fabrication (e.g., after integration of these functions at or near the end of device fabrication) may result in a significant percentage of devices ultimately being rejected due to an inability to test portions of the devices in multiple (e.g., earlier) fabrication stages.

To address these issues, the present disclosure provides some embodiments of an IC device that facilitates same-side electrical and optical testing at multiple stages of fabrication. In some embodiments, a photonic IC (P-IC) structure (e.g., prior to bonding with an electrical IC (E-IC structure) may provide a conductive pad at an upper surface of the P-IC structure that is electrically coupled with a photodetector, as well as a trench that facilitates optical access from the upper surface of the P-IC to an optical edge detector that is optically coupled to the photodetector. Accordingly, the conductive pad and the optical edge detector may be accessed from the upper surface of the P-IC structure to perform electrical-optical testing.

Also, in some embodiments, a combined structure that includes the P-IC structure and an electrical IC (E-IC) structure bonded to the upper surface of the P-IC structure may include another conductive pad at a lower surface of the P-IC structure and a trench that facilitates optical access from the lower surface of the P-IC structure to the optical edge detector. Consequently, the other conductive pad and the optical edge detector may be accessed from the (opposite) lower surface of the P-IC structure to perform electrical-optical testing that incorporates an E-IC die of the E-IC structure.

Accordingly, use of some embodiments of the IC device may provide a more accurate, and hence more useful, same-side simultaneous electrical and optical testing ability that may be performed at multiple stages of device fabrication using currently available testing systems. In some embodiments, this testing ability may result in a more accurate and efficient determination of chip yield, as well as more precise monitoring of IC process health.

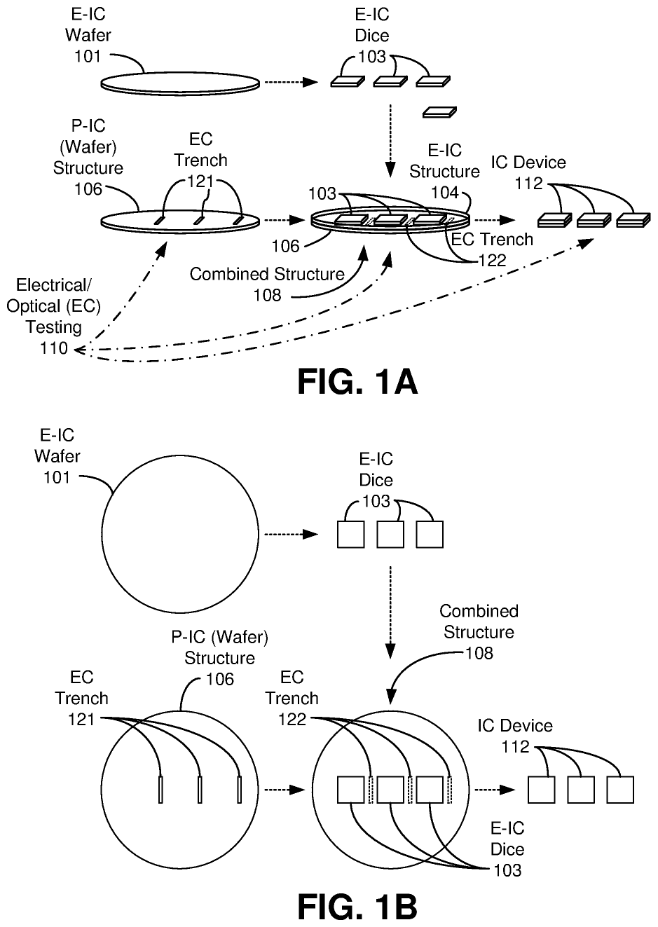

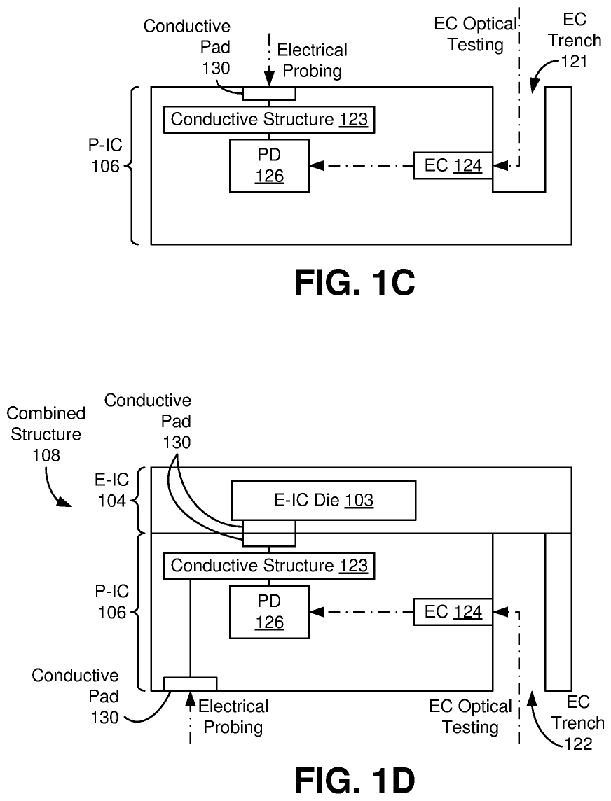

FIGS. 1A and 1B illustrate schematic perspective and plan views, respectively, of some embodiments of fabrication of an integrated circuit (IC) device 112 that facilitates same-side electrical and optical testing at multiple stages of fabrication, according to the present disclosure. As is described in greater detail below, in some embodiments, an electrical IC (E-IC) wafer 101 (e.g., a semiconductor wafer including one or more electrical circuits) and a photonic IC (P-IC) structure 106 (e.g., an optical wafer including one or more photonic structures and associated circuitry) may be fabricated or provided. As described in greater detail below, P-IC structure 106 may include first edge coupling (EC) trenches 121 extending from an upper surface of P-IC structure 106 into P-IC structure 106. Each first EC trench 121 may facilitate access to a corresponding optical edge coupler (not explicitly depicted in FIGS. 1A and 1B) that is optically coupled to a photodetector (also not explicitly depicted in FIGS. 1A and 1B). Consequently, each first EC trench 121, along with a corresponding first conductive pad at the upper surface of P-IC structure 106 (not shown in FIGS. 1A and 1B), may facilitate combined electrical-optical testing 110 of P-IC structure 106 at an early fabrication stage of IC device 112.

Thereafter, after singulating E-IC wafer 101 into multiple E-IC dice 103, E-IC dice 103 may be bonded or otherwise attached to P-IC structure 106 and further supplemented to form an E-IC structure 104 that, with P-IC structure 106, results in a combined structure 108. In some embodiments, P-IC structure 106 may include second EC trenches 122 extending from a lower surface of P-IC structure 106 into P-IC structure 106. Each second EC trench 122 may facilitate access to a corresponding optical edge coupler that is optically coupled to a photodetector, as discussed above. In some embodiments, each second EC trench 122 may substantially align vertically with a corresponding first EC trench 121. Accordingly, each second EC trench 122, along with a corresponding second conductive pad at the lower surface of P-IC structure 106, may facilitate combined electrical-optical testing 110 of combined structure 108 at a later fabrication stage of IC device 112.

Additionally, in some embodiments, after combined structure 108 is singulated into individual IC devices 112, each IC device 112 may undergo electrical-optical testing 110 by way of the optical edge couplers discussed above.

FIGS. 1C and 1D illustrate schematic side views of some embodiments of P-IC structure 106 and subsequent combined structure 108, respectively, that facilitate same-side electrical and optical testing at different stages of fabrication, according to the present disclosure. P-IC structure 106 of FIG. 1C (e.g., prior to bonding with an E-IC die 103) may include an optical edge coupler 124 that is optically coupled with a photodetector (PD) 126 (e.g., a photodiode). P-IC structure 106 may also include at least one conductive pad 130 at a first surface (e.g., an upper surface) of P-IC structure 106 that is coupled to PD 126 by way of a conductive structure 123. Further, P-IC structure 106 may include first EC trench 121 extending from the upper surface of P-IC structure 106 to facilitate optical access to optical EC 124, thus allowing combined electrical probing and edge-coupled optical testing by way of the first surface.

Thereafter, as described above, an E-IC die 103, as part of E-IC structure 104, may be bonded to the upper surface of P-IC structure 106 (e.g., thus covering the opening of first EC trench 121). In some embodiments, in bonding E-IC die 103 to P-IC structure 106, a conductive pad 130 that is electrically connected to E-IC die 103 may contact conductive pad 130 at the first surface of P-IC structure 106, thus electrically coupling E-IC die 103 with PD 126 by way of conductive structure 123. In addition, another conductive pad 130 at the second (e.g., lower) surface of P-IC structure 106 may be electrically coupled to conductive structure 123, and thus to E-IC die 103. Moreover, P-IC structure 106 may include second EC trench 122 (e.g., sharing at least some volume with former first EC trench 121) extending from the second surface of P-IC structure 106 to facilitate optical access to optical EC 124, thus allowing combined electrical probing and edge-coupled optical testing by way of the second surface, as depicted in FIG. 1D.

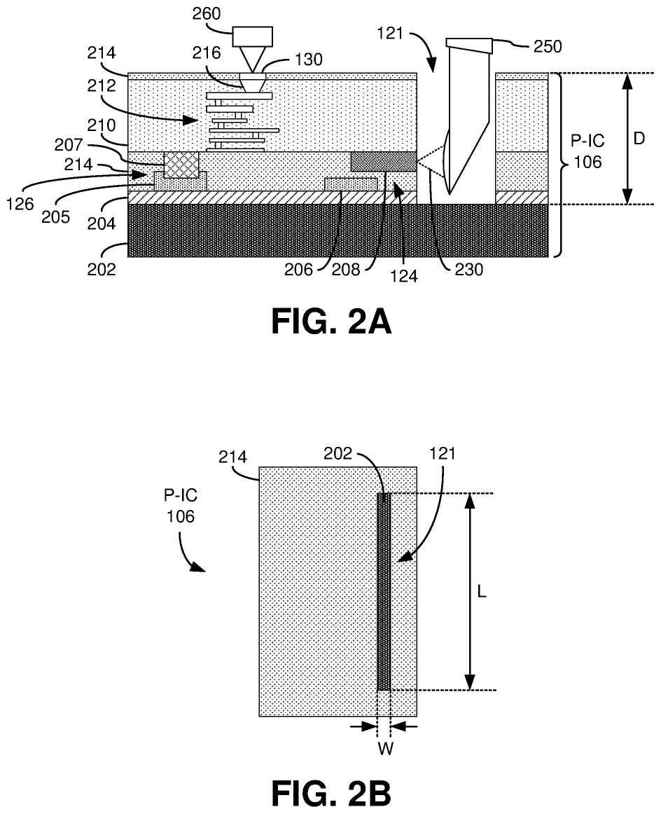

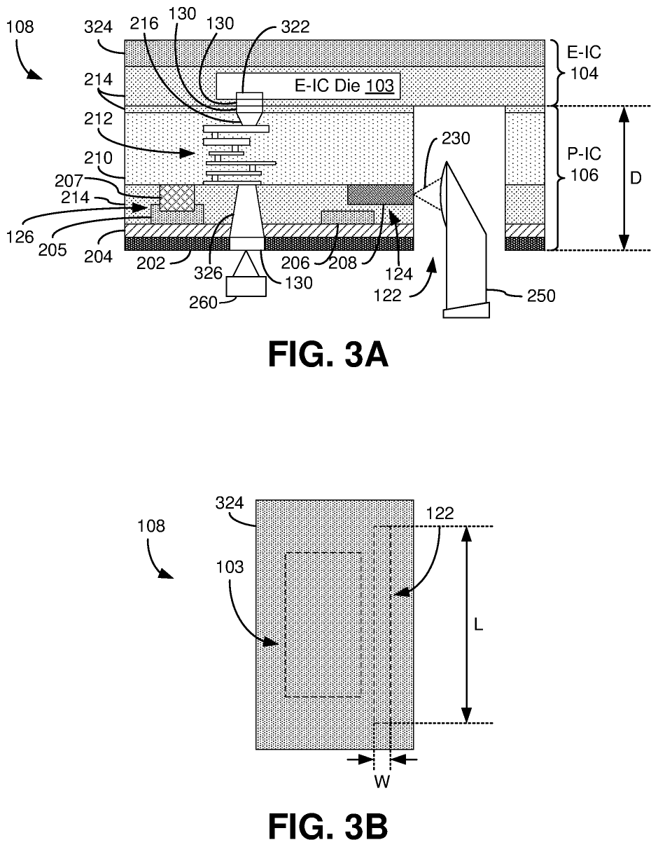

FIGS. 2A and 2B illustrate structural side and plan views, respectively, of some embodiments of a P-IC structure 106 that facilitates same-side electrical and optical testing at a corresponding stage of fabrication, according to the present disclosure. FIG. 2B is presented in a smaller scale relative to FIG. 2A to depict a possible length (L) of first trench 121 relative to a width (W) of first trench 121, discussed in greater detail below. In some embodiments, P-IC structure 106 (e.g., prior to bonding with E-IC structure 104) may include a substrate 202. Examples of materials used in substrate 202 may include, but are not limited to, silicon (Si), silicon dioxide (SiO₂), boron (B), phosphorus (P), or the like. Further, a buried oxide layer 204 may be disposed over substrate 202. In some embodiments, buried oxide layer 204 may be formed by employing an oxygen ion beam implantation process on substrate 202 to create an oxygen-rich layer, which may then be annealed to produce buried oxide layer 204.

In some embodiments, a dielectric layer (e.g., an oxide layer 214) may be disposed over buried oxide layer 204. Examples of materials in oxide layer 214 may include, but are not limited to, silicon oxide (SiOₓ, such as SiO₂), or another oxide or dielectric layer. Within oxide layer 214, optical edge coupler (EC) 124 and photodetector (PD) 126 may be disposed and optically coupled together, such as by way of a waveguide (not explicitly shown in FIG. 2A). In some embodiments, PD 126 may also be coupled to a grating coupler (also not shown in FIG. 2A) to facilitate reception of light via an upper or lower surface of P-IC structure 106.

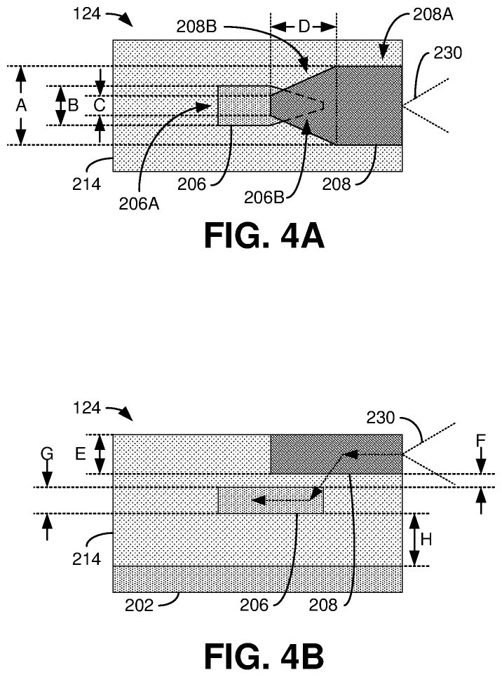

In some embodiments, optical EC 124 may include an upper portion 208 and a lower portion 206 to facilitate transfer of light received at optical EC 124 into a waveguide for transmission to PD 126. An example of optical EC 124 is discussed below in connection with FIGS. 4A and 4B.

In some embodiments, as illustrated in FIG. 2A, PD 126 may include a germanium structure 207 on a silicon structure 205 that forms a photodiode. However, other types of photodetectors, including other forms of photodiodes, may be employed as PD 126.

At least one dielectric layer 210 may be disposed over oxide layer 214, PD 126, and optical EC 124. In some embodiments, the at least one dielectric layer 210 may include one or more dielectric materials, including, but not limited to, silicon oxide (SiOₓ) (e.g., silicon dioxide (SiO₂)), tantalum nitride (TaN), or the like.

Conductive structure 212 may be disposed within the at least one dielectric layer 210. In some embodiments, conductive structure 212 may include vertically-oriented vias and interconnected metal routing layers to electrically couple components within P-IC structure 106. A number n (e.g., six) metal layers and n-1 (e.g., five) intervening vias may be included in conductive structure 212, although greater or fewer numbers of layers and vias are possible in other embodiments. In some embodiments, conductive structure 212 may provide one or more separate electrical connections among the components, such as PD 126. Conductive structure 212 may include, but is not limited to, copper (Cu), tantalum (Ta), manganese (Mn), aluminum (Al), silicon (Si), titanium (Ti), tungsten (W), other metals or alloys, or other conductive materials.

A via 216 (e.g., a through-dielectric via (TDV)) may disposed at an upper surface of the at least one dielectric layer 210 and may be electrically connected with conductive structure 212. In some embodiments, via 216 may be a conductive material, such as one or more of the conductive materials listed above for conductive structure 212.

Another dielectric structure (e.g., oxide layer 214) may be disposed over the at least one dielectric layer 210 to form an upper surface of P-IC structure 106. In some embodiments, oxide layer 214 may include the same dielectric material as oxide layer 214 disposed below the at least one dielectric layer 210, or may include a different dielectric material.

A first conductive pad 130 may be disposed at the upper surface of P-IC structure 106 (e.g., in oxide layer 214). First conductive pad 130 may contact via 216, thus being electrically connected to PD 126 via conductive structure 212. In some embodiments, first conductive pad 130 may include one or more conductive materials, such as those discussed above in conjunction with conductive structure 212 and/or via 216. Thus, as indicated in FIG. 2A, first conductive pad 130 may facilitate engagement with an electrical probe 260 (e.g., a probe of a circuit probe (CP) testing machine) from above P-IC structure 106.

P-IC structure 106 may also include a first trench 121 that extends from the upper surface of P-IC structure 106 toward substrate 202. In some embodiments, first trench 121 may extend to an upper surface of substrate 202, possibly to some point above substrate 202, or possibly into substrate 202. Also, in some embodiments, first trench 121 may be configured to facilitate optical access to optical EC 124 (e.g., by exposing a portion of optical EC 124 to first trench 121). In some embodiments, first trench 121 may possess dimensions that allow first trench 121 to receive an optical probe 250 from above P-IC structure 106 that may emit light as an optical signal to optical EC 124 that may then forward the signal to PD 126 (e.g., by way of a waveguide). For example, as depicted in FIGS. 2A and 2B, first trench 121 may be at least 10 microns (μm) in width (W), at least 50 μm in depth (D), and at least 200 μm in length (L). In some embodiments, first trench 121 may be approximately 60 microns (μm) in width (W), 95 μm in depth (D), and 1500 μm in length (L). In some embodiments, the sidewall of first trench 121 at which upper portion 208 of optical EC 124 is located may be substantially vertical (e.g., perpendicular to substrate 202, as illustrated in FIG. 2A), while in other embodiments, the sidewall may be more angled relative to vertical.

Accordingly, given embodiments of P-IC structure 106 of FIGS. 2A and 2B, combined electrical and optical testing 110 of P-IC structure 106 (e.g., prior to bonding of an E-IC structure thereon) may thus be performed by way of electrical probe 260 making contact with first conductive pad 130 and optical probe 250 providing light signals via optical EC 124 in first trench 121. Such combined electrical and optical testing may be performed from above the upper surface of P-IC structure 106.

FIGS. 3A and 3B illustrate structural side and plan views, respectively, of some embodiments of a combined P-IC/E-IC structure 108 that facilitates same-side electrical and optical testing at a corresponding stage of fabrication, according to the present disclosure. FIG. 3B is presented in a smaller scale relative to FIG. 3A to depict a possible length (L) of a second trench 121 relative to a width (W) of second trench 122, discussed in greater detail below.

As depicted in FIGS. 3A and 3B, P-IC structure 106 of combined structure 108 includes many or all of the components discussed above with respect to P-IC structure 106 of FIGS. 2A and 2B. Differences therefrom are discussed in greater detail below.

At the stage of fabrication illustrated in FIGS. 3A and 3B, E-IC structure 104, including an E-IC die 103, is bonded to the upper surface of P-IC structure 106. In some embodiments, E-IC die 103 may include logic circuitry that controls PD 126, captures data therefrom, and/or processes such data. Also, in some embodiments, E-IC die 103 may include a conductive structure 322 that is electrically connected to a second conductive pad 130 surrounded by an oxide layer 214. Accordingly, E-IC structure 104 may be bonded to P-IC structure 106 by way of second conductive pad 130 of E-IC structure 104 being bonded with first conductive pad 130 of E-IC die 103 and/or an oxide layer 214 surrounding second conductive pad 130 being bonded with oxide layer 214 at the upper surface of P-IC structure 106. In some embodiments, such bonding may be performed by way of a heat-based bonding process. In some embodiments, such bonding may close an open end of first trench 121.

In some embodiments, a carrier 324 (e.g., a silicon (Si) carrier) may be disposed over E-IC die 103 to facilitate handling of combined structure 108 during subsequent fabrication stages of IC device 112. Carrier 324 may be provided in preparation for a narrowing, or “thinning-down,” of substrate 202 of P-IC structure 106, as shown in FIG. 3A. E-IC die 103, carrier 324, second conductive pad 130, and associated oxide layer 214 are referred to herein as E-IC structure 104.

As indicated in FIG. 3A, in addition to thinned down substrate 202, P-IC structure 106 may include a newly formed via 326 that extends through buried oxide layer 204 and adjacent oxide layer 214 and contacts conductive structure 212 (e.g., at a lower metal layer thereof). A third conductive pad 130 is disposed in substrate 202 and contacts via 326. In some embodiments, via 326 may be a TDV in a manner similar to that of via 216, described above. In some embodiments, third conductive pad 130 may include one or more conductive materials, such as those discussed above in conjunction with first and second conductive pads 130. Therefore, as indicated in FIG. 3A, third conductive pad 130 may facilitate engagement with electrical probe 260 from below P-IC structure 106.

P-IC structure 106 also includes second trench 122 that extends from the lower surface of P-IC structure 106, at substrate 202, toward E-IC structure 104. In some embodiments, second trench 122 may extend to a lower surface of E-IC structure 104, possibly to some point below E-IC structure 104, or possibly into E-IC structure 104. Also, in some embodiments, second trench 122 may be configured to facilitate optical access to optical EC 124 (e.g., by exposing a portion of optical EC 124 to second trench 122). In some embodiments, as with first trench 121, second trench 122 may possess dimensions that allow second trench 122 to receive optical probe 250 from below P-IC structure 106 that may emit light as an optical signal to optical EC 124 that may then forward the signal to PD 126 (e.g., by way of a waveguide). For example, as illustrated in FIGS. 3A and 3B, second trench 122 may be at least 10 microns (μm) in width (W), at least 50 μm in depth (D), and at least 200 μm in length (L). In some embodiments, second trench 122 may be approximately 60 microns (μm) in width (W), 95 μm in depth (D), and 1500 μm in length (L). Also, some embodiments, second trench 122 may have a length that matches or exceeds a width or length of E-IC die 103, as shown in FIG. 3B. Further, in some embodiments, second trench 122 substantially aligns vertically with the prior first trench 121, and may be at least as wide, and perhaps wider, than first trench 121. Further, in some embodiments, the sidewall of second trench 122 at which upper portion 208 of optical EC 124 is located may be substantially vertical (e.g., perpendicular to substrate 202, as depicted in FIG. 3A), while in other embodiments, the sidewall may be more angled relative to vertical.

Consequently, given embodiments of combined structure 108 of FIGS. 3A and 3B, combined electrical and optical testing 110 of combined structure 108 (e.g., including testing of E-IC die 103 in conjunction with P-IC structure 106 after the bonding of E-IC die 103 to P-IC structure 106) may thus be performed by way of electrical probe 260 making contact with third conductive pad 130 and optical probe 250 providing light signals via optical EC 124 in second trench 122. Such combined electrical and optical testing may be performed by way of the lower surface of P-IC structure 106, which is opposite the upper surface by which combined electrical-optical testing 110 may occur prior to the bonding of E-IC structure 104 to P-IC structure 106. In some embodiments, combined structure 108 may be flipped or inverted relative to that shown in FIG. 3A so that all combined electrical-optical testing may occur from above.

FIGS. 4A and 4B illustrate structural plan and side views, respectively, of some embodiments of optical EC 124 for IC device 112 that facilitates same-side electrical and optical testing at multiple stages of fabrication, according to the present disclosure. As indicated above, optical EC 124 may include upper portion 208 and lower portion 206 disposed within oxide layer 214. In some embodiments, as depicted in the plan view of FIG. 4A, upper portion 208 may have a first rectangular section 208A and a laterally tapering section 208B, and lower portion 206 may have a second rectangular section 206A and a laterally inverse tapering section 206B. In some embodiments, upper portion 208 may include silicon mononitride (SiN) and lower portion 206 may include silicon (Si). However, employing other optically-transmissive materials for upper portion 208 and lower portion 206 is also possible. In some embodiments, upper portion 208 receives light 230 (e.g., from an optical fiber or optical probe 250, as depicted in FIGS. 2A and 3A) of a first spot size and forwards the light to lower portion 206 to reduce the spot size for transmission to PD 126 by way of a waveguide.

As illustrated in FIGS. 4A and 4B, laterally tapering section 208B at least partially overlaps, and may fully overlap, laterally inverse tapering section 206B. Also, in some embodiments, upper portion 208 may be vertically separated from lower portion 206 within oxide layer 214 by a thickness less than the thickness of either or both upper portion 208 and lower portion 206. Further, in some embodiments, with respect to the various denoted dimensions A through H of FIGS. 3A and 3B, A may be approximately 800 nanometers (nm), B may be approximately 370 nm, C may be approximately 200 nm, D may be approximately 30 μm, E may be approximately 400 nm, F may be approximately 100 nm, G may be approximately 270 nm, and H may be approximately 2000 nm. However, other dimensions may be employed in a similarly configured optical EC 124 in other embodiments. Moreover, other types or configurations of optical edge ECs that couple received light into a waveguide for transmission within oxide layer 214 to PD 126 may be employed in other embodiments.

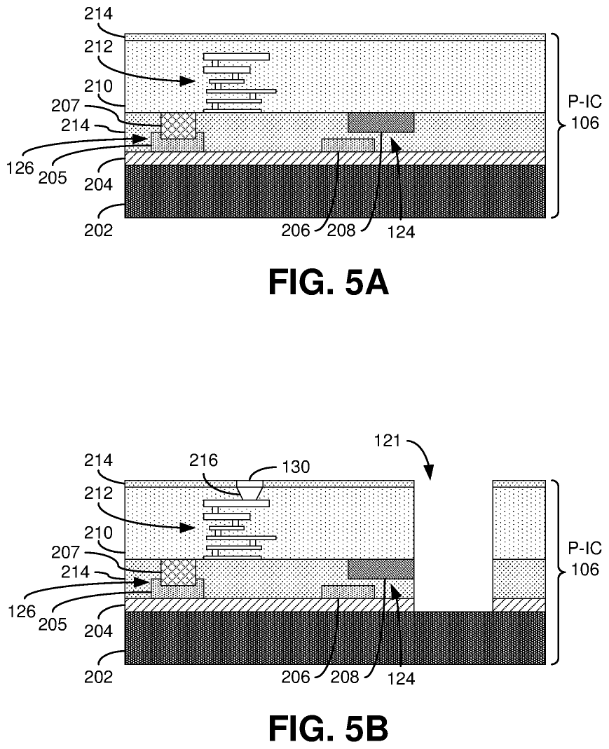

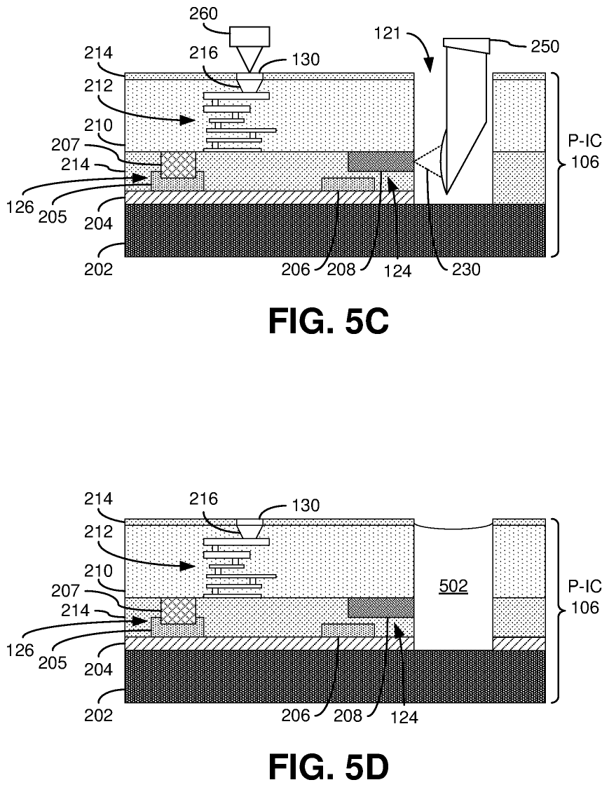

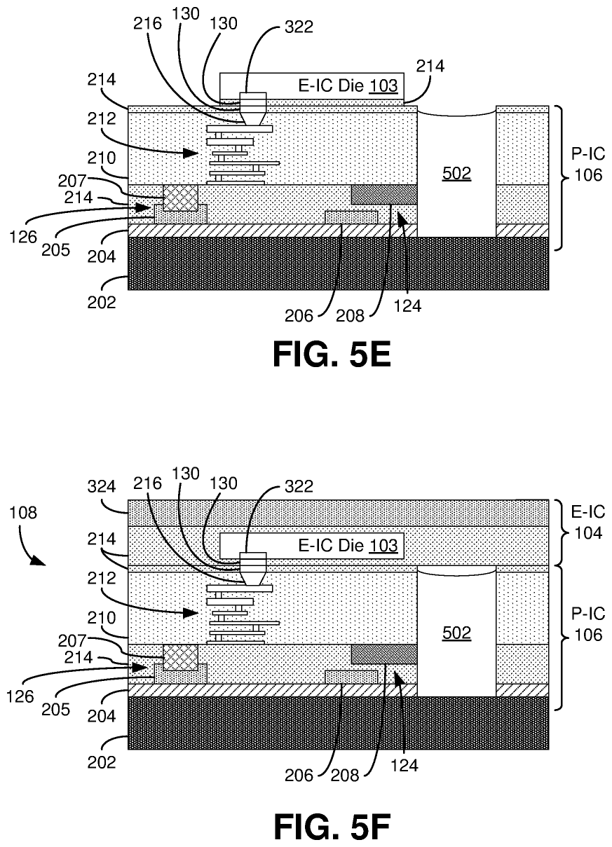

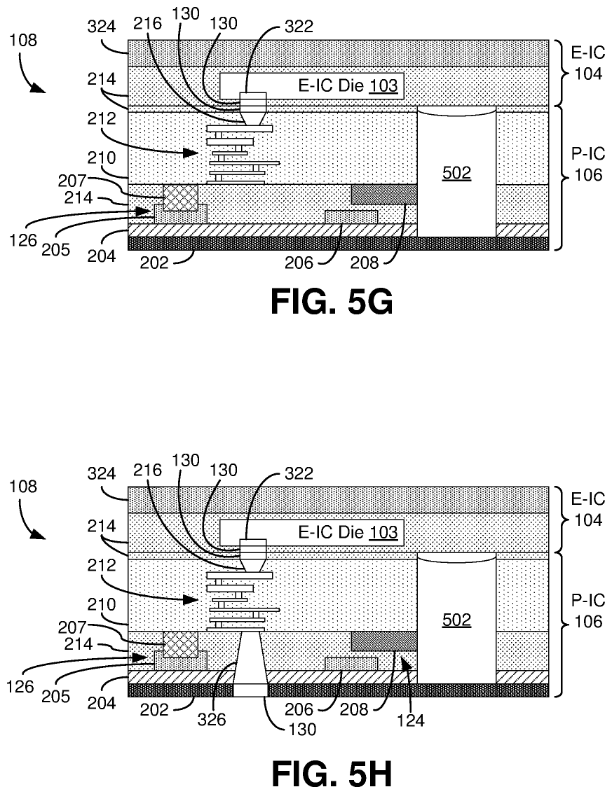

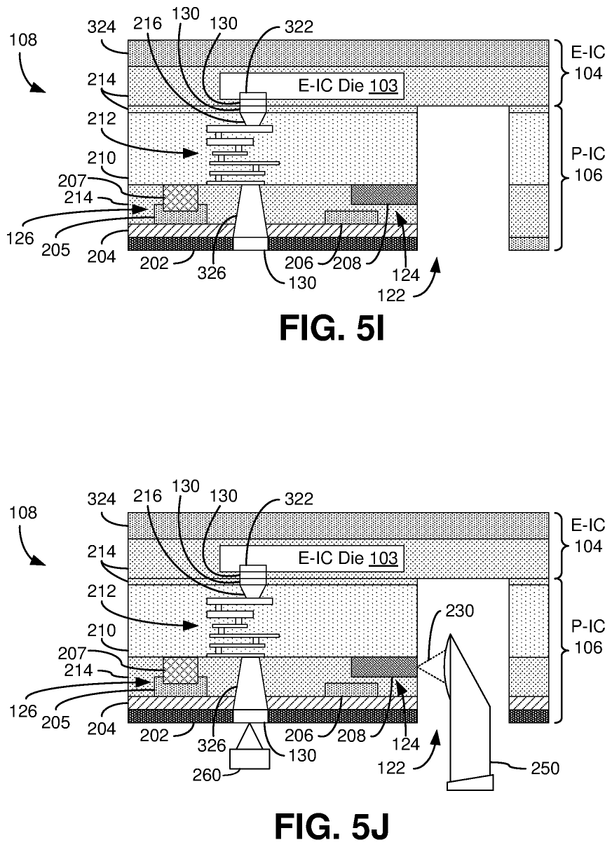

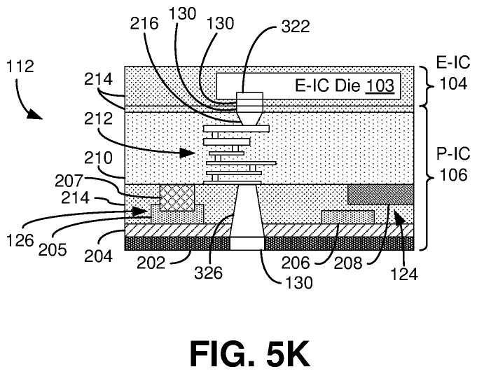

FIGS. 5A through 5K illustrate cross-sectional views of some embodiments of a semiconductor structure including an optical edge coupler (e.g., optical EC 124) for an IC device (e.g., IC device 112) at multiple stages of manufacture that facilitates same-side electrical and optical testing, according to the present disclosure. Although FIGS. 5A through 5K are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIG. 5A illustrates a P-IC structure 106 upon which subsequent operations may be performed to facilitate combined electrical and optical testing thereon. As described above in connection with FIG. 2A, P-IC structure 106 may include substrate 202 (e.g., a silicon substrate) over which buried oxide layer 204 may be disposed. Oxide layer 214, or a layer of another dielectric material, may be disposed over buried oxide layer 204. Within oxide layer 214, optical EC 124 and PD 126 may be disposed and optically coupled together, such as by way of a waveguide (not explicitly shown in FIG. 5A). In some embodiments, optical EC 124 may include an upper portion 208 and a lower portion 206, as discussed above, to facilitate transfer of light received at optical EC 124 into a waveguide for transmission to PD 126. Also, in some embodiments, PD 126 may include a germanium structure 207 on a silicon structure 205 that forms a photodiode. However, other types of photodetectors, including other forms of photodiodes, may be employed as PD 126. P-IC structure 106 may also include conductive structure 212 within at least one dielectric layer 210 disposed over oxide layer 214, where conductive structure 212 may be electrically coupled to PD 126. Further, additional oxide layer 214 may be disposed over at the at least one dielectric layer 210. The various possible materials included in each of these components may be as discussed above in conjunction with FIG. 2A.

In some embodiments, the forming of each of the components of P-IC structure 106 illustrated in FIG. 5A may begin with the provision of substrate 202, and continue with the forming of the various layers (e.g., beginning with buried oxide layer 204) and enclosed components (e.g., optical EC coupler 124 and PD 126) by way of a series of forming (e.g., deposition) and etching operations, ending with the deposition of additional oxide layer 214 over the at least one dielectric layer 210.

FIG. 5B illustrates the forming (e.g., etching and deposition) of additional features of P-IC structure 106 to facilitate combined electrical and optical testing of P-IC structure 106, as described above in conjunction with FIG. 2A. More specifically, additional oxide layer 214 and the underlying at least one dielectric layer 210 may be etched and subsequently filled at the upper surface of P-IC structure 106 with a conductive material to form via 216 (e.g., through-dielectric via, or TDV) and first conductive pad 130 to create an electrical connection between first conductive pad 130 and PD 126 by way of via 216 and conductive structure 212. In some embodiments, first conductive pad 130 is dimensioned to engage an electrical probe (e.g., electrical probe 260), as discussed above in connection with FIG. 2A.

FIG. 5B also illustrates the forming (e.g., etching) of first EC trench 121 via additional oxide layer 214 at the upper surface of P-IC structure 106 toward substrate 202. Such etching may end at substrate 202, just prior to reaching substrate 202, or within substrate 202. As discussed above, first EC trench 121 may be dimensioned to accommodate insertion of an optical probe (e.g., optical probe 250) into first EC trench 121 to emit light into optical EC 124 for transmission to PD 126.

FIG. 5C illustrates the use of optical probe 250 in first EC trench 121 and the engagement of electrical probe 260 with first conductive pad 130 to perform combined electrical and optical testing of P-IC structure 106, including PD 126 and optical EC 124. In some embodiments, P-IC structure 106 may include a plurality of PDs 126, optical ECs 124, and associated first conductive pads 130, first EC trenches 121, and the like, within a single P-IC wafer, as indicated in FIGS. 1A and 1B.

In some embodiments, FIGS. 5D through 5J depict stages of fabrication that may describe a transformational process from P-IC structure 106 of FIG. 2A to combined structure 108 of FIG. 3A. For example, FIG. 5D illustrates the forming (e.g., deposition) of a fill material (e.g., a conductive material 502, such as copper (Cu) or another metal, alloy, or other conductive material) in first EC trench 121. In some embodiments, conductive material 502 is formed to prevent damage to optical EC 124 or other portions of P-IC structure 106 during subsequent fabrication steps discussed below.

FIG. 5E illustrates the joining (e.g., bonding) of E-IC die 103 with the upper surface of P-IC structure 106. In some embodiments, another oxide layer 214 may be formed (e.g., deposited) on a lower surface of E-IC die 103 and subsequently etched and filled with conductive material to form second conductive pad 130 in contact with conductive structure 322 of E-IC die 103. Thereafter, E-IC die 103 may be bonded to the upper surface of P-IC structure 106 (e.g., by way of heat-based bonding) to bond first and second conductive pads 130 and associated oxide layers 214, thus creating an electrical connection between E-IC die 103 and PD 126 by way of conductive structure 212 and via 216.

FIG. 5F illustrates the filling (e.g., deposition) of additional dielectric material (e.g., additional oxide layer 214 material) and joining (e.g., bonding) of carrier 324 (e.g., a silicon carrier, as described above in connection with FIG. 3A) onto E-IC die 103 and P-IC structure 106 to create combined structure 108. In some embodiments, additional oxide layer 214 material and carrier 324 may provide mechanical stability for combined structure 108 during the subsequent processing steps described below.

For example, FIG. 5G illustrates the thinning-down or narrowing (e.g., by way of chemical-mechanical planarization (CMP)) of substrate 202 (e.g., to facilitate access to conductive structure 212 by way of the lower surface of P-IC structure 106).

FIG. 5H illustrates the forming (e.g., etching and filling or deposition) of via 326 and corresponding third conductive pad 130 through substrate 202, buried oxide layer 204, and oxide layer 214 such that third conductive pad 130 may be electrically coupled with E-IC die 103 and/or PD 126.

FIG. 5I illustrates the forming (e.g., etching) of second EC trench 122, extending from the lower surface of P-IC structure 106 toward, and possibly up to or into, oxide layer 214 of E-IC structure 104. As shown, the forming of second EC trench 122 may completely remove conductive material 502 previously disposed in first EC trench 121. Accordingly, the width of second EC trench 122 may be equal to or greater than the width of previous first EC trench 121 (e.g., to once again facilitate access to optical EC 124 by optical probe 250.

FIG. 5J illustrates the use of optical probe 250 in second EC trench 122 and the engagement of electrical probe 260 with third conductive pad 130 to perform combined electrical and optical testing of combined structure 108, including E-IC die 103, PD 126, and optical EC 124. In some embodiments, combined structure 108 may include a plurality of E-IC dice 103, PDs 126, optical ECs 124, and associated third conductive pads 130, second EC trenches 122, and the like, in conjunction with a single P-IC wafer, as indicated in FIGS. 1A and 1B.

FIG. 5K illustrates the separation (e.g., singulation or dicing) of an individual IC device 112 from combined structure 108, as depicted in FIGS. 1A and 1B, as described above. In some embodiments, additional combined electrical and optical testing of IC device 112 (e.g., as indicated in FIG. 1A) may be performed via third conductive pad 130 at the bottom surface of IC device 112 and optical EC 124 at a side surface of IC device 112. Further, in some embodiments, several such IC devices 112 may be produced from a single P-IC wafer, as indicated in FIGS. 1A and 1B.

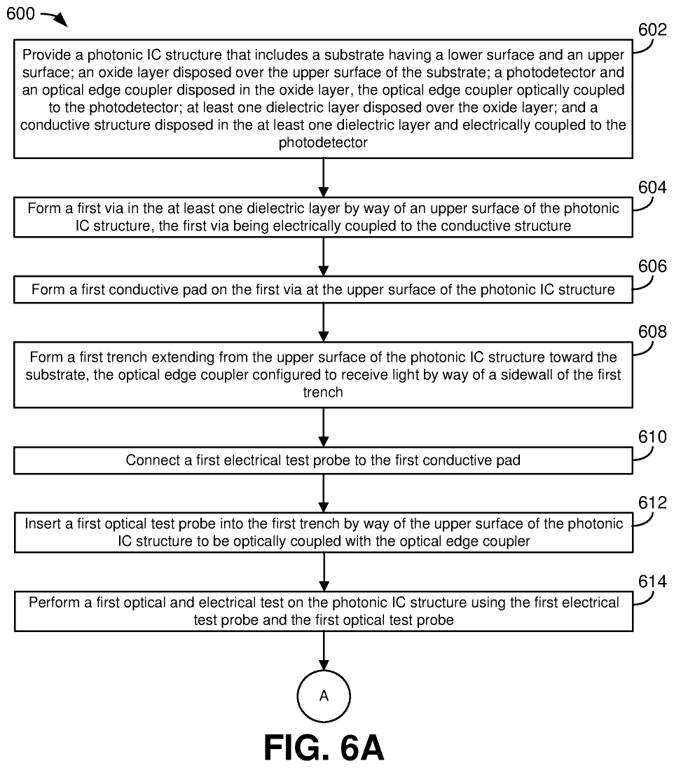

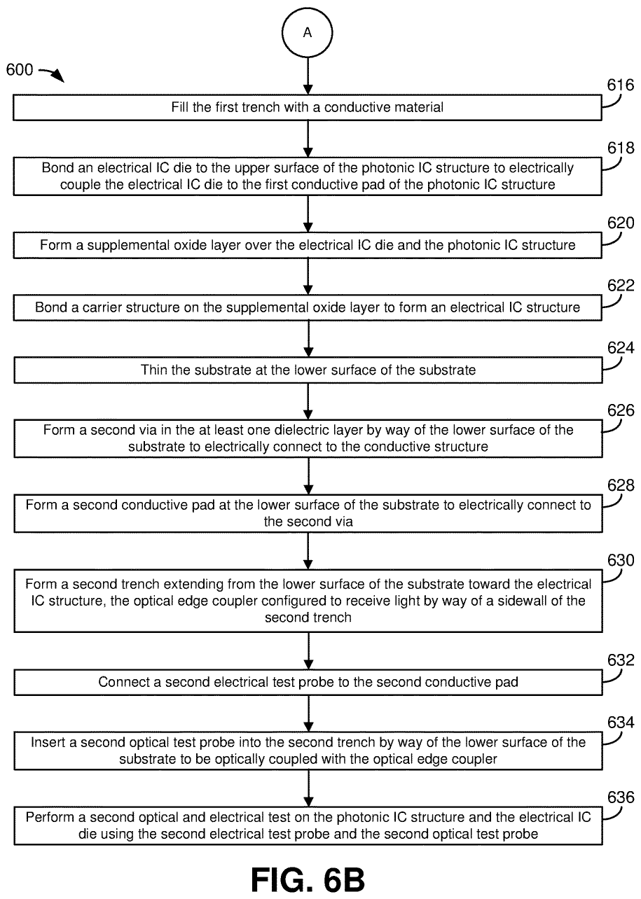

FIGS. 6A and 6B illustrate some embodiments of a methodology 600 of forming the semiconductor structure of FIGS. 5A through 5K, in accordance with the present disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

In some embodiments, Acts 602 through 614 of FIG. 6A may correspond to FIG. 1C, FIGS. 2A and 2B, and FIGS. 5A through 5C associated with testing of P-IC structure 106, while Acts 616 through 636 may correspond to FIG. 1D, FIGS. 3A and 3B, and FIGS. 5D through 5J. At Act 602 of FIG. 6A, for example, photonic IC structure (e.g., P-IC structure 106 of FIG. 2A) may be provided. In some embodiments, the photonic IC structure may include a substrate (e.g., substrate 202 of FIG. 2A) having a lower surface and an upper surface; an oxide layer (e.g., oxide layer 204 of FIG. 2A); a photodetector (e.g. PD 126 of FIG. 2A) and an optical edge coupler (e.g., optical EC 124 of FIG. 2A) disposed in the oxide layer, the optical edge coupler optically coupled to the photodetector; at least one dielectric layer (e.g., the at least one dielectric layer 210 of FIG. 2A) disposed over the oxide layer; and a conductive structure (e.g., conductive structure 212 of FIG. 2A) disposed in the at least one dielectric layer and electrically coupled to the photodetector. FIG. 5A illustrates a cross-sectional view of some embodiments corresponding to Act 602.

At Act 604, a first via (e.g., via 216) may be formed in the at least one dielectric layer by way of an upper surface of the photonic IC structure, the first via being electrically coupled to the conductive structure. At Act 606, a first conductive pad (e.g., first conductive pad 130 of FIG. 2A) may be formed on the first via at the upper surface of the photonic IC structure. At Act 608, a first trench (e.g., first EC trench 121 of FIG. 2A) extending from the upper surface of the photonic IC structure toward the substrate may be formed, the optical edge coupler being configured to receive light by way of a sidewall of the first trench. FIG. 5B illustrates a cross-sectional view of some embodiments corresponding to Acts 604, 606, and 608.

At Act 610, a first electrical test probe (e.g., electrical probe 260 of FIG. 2A) may be connected to the first conductive pad. At Act 612, a first optical test probe (e.g., optical probe 250 if FIG. 2A) may be inserted into the first trench by way of the upper surface of the photonic IC structure to be optically coupled with the optical edge coupler. At Act 614, a first optical and electrical test may be performed on the photonic IC structure using the first electrical test probe and the first optical test probe. FIG. 5C illustrates a cross-sectional view of some embodiments corresponding to Acts 610, 612, and 614.

Continuing with FIG. 6B, at Act 616, the first trench may be filled with a conductive material (e.g., conductive material 502 of FIG. 3A). FIG. 5D illustrates a cross-sectional view of some embodiments corresponding to Act 616.

At Act 618, an electrical IC die (e.g., E-IC die 103 of FIG. 3A) may be bonded to the upper surface of the photonic IC structure to electrically couple the electrical IC die to the first conductive pad of the photonic IC structure. FIG. 5E illustrates a cross-sectional view of some embodiments corresponding to Act 618.

At Act 620, a supplemental oxide layer (e.g., oxide layer 214 of FIG. 3A) may be formed over the electrical IC die and the photonic IC structure. Further, at Act 622, a carrier structure (e.g., carrier 324 of FIG. 3A) may be bonded on the supplemental oxide layer to form an electrical IC structure (e.g., E-IC structure 104 of FIG. 3A). FIG. 5F illustrates a cross-sectional view of some embodiments corresponding to Acts 620 and 622.

At Act 624, the substrate may be thinned (e.g., narrowed or thinned-down) at the lower surface of the substrate. FIG. 5G illustrates a cross-sectional view of some embodiments corresponding to Act 624.

At Act 626, a second via (e.g., via 326 of FIG. 3A) may be formed in the at least one dielectric layer by way of the lower surface of the substrate to electrically connect to the conductive structure. At Act 628, a second conductive pad (e.g., second conductive pad 130 of FIG. 3A) may be formed at the lower surface of the substrate to electrically connect to the second via. FIG. 5H illustrates a cross-sectional view of some embodiments corresponding to Acts 626 and 628.

At Act 630, a second trench (e.g., second EC trench 122 of FIG. 3A) extending from the lower surface of the substrate toward the electrical IC structure may be formed, the optical edge coupler being configured to receive light by way of a sidewall of the second trench. FIG. 5I illustrates a cross-sectional view of some embodiments corresponding to Act 630.

At Act 632, a second electrical test probe (e.g., electrical probe 260 of FIG. 3A) may be connected to the second conductive pad. At Act 634, a second optical test probe (e.g., optical probe 250 of FIG. 3A) may be inserted into the second trench by way of the lower surface of the substrate to be optically coupled with the optical edge coupler. At Act 636, second optical and electrical test may be performed on the photonic IC structure and the electrical IC die using the second electrical test probe and the second optical test probe. FIG. 5J illustrates a cross-sectional view of some embodiments corresponding to Acts 632, 634, and 636.

Some embodiments relate to an integrated circuit (IC) device. The device includes a substrate including a first surface and a second surface; a first dielectric layer disposed over the second surface of the substrate; a photodetector and an optical edge coupler disposed in the first dielectric layer, the optical edge coupler optically coupled to the photodetector; at least one dielectric layer disposed over the first dielectric layer; a conductive structure disposed in the at least one dielectric layer; a conductive pad disposed at a surface of the IC device, the conductive pad electrically coupled to the photodetector by way of the conductive structure; and a trench extending from the surface of the IC device toward the substrate, the optical edge coupler configured to receive light from a sidewall of the trench.

Some embodiments relate to another IC device. The device includes an electrical IC structure including an electrical IC die; and a first conductive pad disposed at a surface of the electrical IC structure and electrically coupled to the electrical IC die; and a photonic IC structure disposed proximate the surface of the electrical IC structure, the photonic IC structure including: a substrate including a first surface and a second surface; a first dielectric layer disposed over the second surface of the substrate; a photodetector and an optical edge coupler disposed in the first dielectric layer, the optical edge coupler optically coupled to the photodetector; at least one dielectric layer disposed over the first dielectric layer; a conductive structure disposed in the at least one dielectric layer; a second conductive pad disposed at a surface of the photonic IC structure and contacting the first conductive pad, the second conductive pad electrically coupled to the photodetector by way of the conductive structure; a third conductive pad disposed at the first surface of the substrate and electrically coupled to the conductive structure; and a trench extending from the first surface of the substrate toward the electrical IC structure, the optical edge coupler configured to receive light from a sidewall of the trench.

Some embodiments relate to a method. The method includes providing a photonic IC structure, the photonic IC structure including: a substrate including a first surface and a second surface; a first dielectric layer disposed over the second surface of the substrate; a photodetector and an optical edge coupler disposed in the first dielectric layer, the optical edge coupler optically coupled to the photodetector; at least one dielectric layer disposed over the first dielectric layer; and a conductive structure disposed in the at least one dielectric layer and electrically coupled to the photodetector; forming a first via in the at least one dielectric layer by way of a surface of the photonic IC structure, the first via being electrically coupled to the conductive structure; forming a first conductive pad on the first via at the surface of the photonic IC structure; and forming a first trench extending from the surface of the photonic IC structure toward the substrate such that the optical edge coupler is configured to receive light from a sidewall of the first trench.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a substrate including a first surface and a second surface;
a first dielectric layer disposed over the second surface of the substrate;
a photodetector and an optical edge coupler disposed in the first dielectric layer, the optical edge coupler optically coupled to the photodetector;
at least one dielectric layer disposed over the first dielectric layer;
a conductive structure disposed in the at least one dielectric layer;
a conductive pad disposed at a surface of the IC device, the conductive pad electrically coupled to the photodetector by way of the conductive structure; and
a trench extending from the surface of the IC device toward the substrate, the optical edge coupler configured to receive light from a sidewall of the trench.

2. The IC device of claim 1, the trench extending to the second surface of the substrate.

3. The IC device of claim 1, further comprising a buried oxide layer disposed on the second surface of the substrate.

4. The IC device of claim 1, the optical edge coupler comprising:
a first layer comprising a first optically transmissive material, the first layer comprising a first rectangular section and a laterally tapering section contacting the first rectangular section; and
a second layer comprising a second optically transmissive material, the second layer comprising a laterally inverse tapering section and a second rectangular section, the laterally inverse tapering section disposed at least partially overlapping the laterally tapering section of the first layer in a plan view.

5. The IC device of claim 4, wherein the first layer is vertically separated from the second layer within the first dielectric layer.

6. The IC device of claim 4, the first optically transmissive material comprising silicon mononitride (SiN) and the second optically transmissive material comprising silicon (Si).

7. The IC device of claim 1, the photodetector comprising a photodiode disposed laterally from the optical edge coupler.

8. The IC device of claim 1, the trench having a width greater than or equal to 50 microns (μm), a length greater than or equal to 200 μm, and a depth greater than or equal to 10 μm.

9. An integrated circuit (IC) device, comprising:
an electrical IC structure comprising:
an electrical IC die; and
a first conductive pad disposed at a surface of the electrical IC structure and electrically coupled to the electrical IC die; and
a photonic IC structure disposed proximate the surface of the electrical IC structure, the photonic IC structure comprising:
a substrate including a first surface and a second surface;
a first dielectric layer disposed over the second surface of the substrate;
a photodetector and an optical edge coupler disposed in the first dielectric layer, the optical edge coupler optically coupled to the photodetector;
at least one dielectric layer disposed over the first dielectric layer;
a conductive structure disposed in the at least one dielectric layer;
a second conductive pad disposed at a surface of the photonic IC structure and contacting the first conductive pad, the second conductive pad electrically coupled to the photodetector by way of the conductive structure;
a third conductive pad disposed at the first surface of the substrate and electrically coupled to the conductive structure; and
a trench extending from the first surface of the substrate toward the electrical IC structure, the optical edge coupler configured to receive light from a sidewall of the trench.

10. The IC device of claim 9, the trench extending to the surface of the electrical IC structure.

11. The IC device of claim 9, the electrical IC structure further comprising a carrier structure disposed over the electrical IC die.

12. The IC device of claim 9, the optical edge coupler comprising:
a first layer comprising a first optically transmissive material, the first layer comprising a first rectangular section and a laterally tapering section contacting the first rectangular section; and
a second layer comprising a second optically transmissive material, the second layer comprising a laterally inverse tapering section and a second rectangular section, the laterally inverse tapering section disposed at least partially overlapping the laterally tapering section of the first layer in a plan view.

13. The IC device of claim 12, wherein the first layer is vertically separated from the second layer within the first dielectric layer.

14. The IC device of claim 9, the photonic IC structure further comprising a via electrically connecting the third conductive pad to the conductive structure.

15. The IC device of claim 9, the trench having a width greater than or equal to 50 microns (μm), a length greater than or equal to 200 μm, and a depth greater than or equal to 10 μm.

16. A method, comprising:
providing a photonic IC structure, the photonic IC structure comprising:
a substrate including a first surface and a second surface;
a first dielectric layer disposed over the second surface of the substrate;
a photodetector and an optical edge coupler disposed in the first dielectric layer, the optical edge coupler optically coupled to the photodetector;
at least one dielectric layer disposed over the first dielectric layer; and
a conductive structure disposed in the at least one dielectric layer and electrically coupled to the photodetector;
forming a first via in the at least one dielectric layer by way of a surface of the photonic IC structure, the first via being electrically coupled to the conductive structure;
forming a first conductive pad on the first via at the surface of the photonic IC structure; and
forming a first trench extending from the surface of the photonic IC structure toward the substrate such that the optical edge coupler is configured to receive light from a sidewall of the first trench.

17. The method of claim 16, further comprising:
connecting a first electrical test probe to the first conductive pad;
inserting a first optical test probe into the first trench by way of the surface of the photonic IC structure to be optically coupled with the optical edge coupler; and
performing a first optical and electrical test on the photonic IC structure using the first electrical test probe and the first optical test probe.

18. The method of claim 16, further comprising:
filling the first trench with a conductive material;
bonding an electrical IC die to the surface of the photonic IC structure to electrically couple the electrical IC die to the first conductive pad of the photonic IC structure;
forming a supplemental dielectric layer over the electrical IC die and the photonic IC structure;
bonding a carrier structure on the supplemental dielectric layer to form an electrical IC structure;
thinning the substrate at the first surface of the substrate;
forming a second via in the at least one dielectric layer by way of the first surface of the substrate to electrically connect to the conductive structure;
forming a second conductive pad at the first surface of the substrate to electrically connect to the second via; and
forming a second trench extending from the first surface of the substrate toward the electrical IC structure such that the optical edge coupler is configured to receive light from a sidewall of the second trench.

19. The method of claim 18, wherein the forming of the second trench removes the conductive material from the first trench.

20. The method of claim 18, further comprising:
connecting a second electrical test probe to the second conductive pad;
inserting a second optical test probe into the second trench by way of the first surface of the substrate to be optically coupled with the optical edge coupler; and
performing a second optical and electrical test on the photonic IC structure and the electrical IC die using the second electrical test probe and the second optical test probe.
